(19) United States
(12) Patent Application Publication
(10) Pub. No.: US 2026/0293124 A1
(43) Pub. Date: Sep. 24, 2026

(54) SEMICONDUCTOR DEVICE AND METHOD FOR FABRICATING THE SAME

(71) Applicant: SK hynix Inc., Gyeonggi-do (KR)

(72) Inventors: Hyo Jun LEE, Gyeonggi-do (KR); Geon Hee KIM, Gyeonggi-do (KR); Han Bit KIM, Gyeonggi-do (KR)

(21) Appl. No.: 19/319,651

(22) Filed: Sep. 4, 2025

(30) Foreign Application Priority Data
Mar. 24, 2025 (KR) 10-2025-0037267

(51) Int. Cl. H10B 12/00; H01L 23/528; H01L 23/532; H01L 23/544

(52) U.S. Cl. CPC H10B 12/50; H10B 12/0335; H10B 12/315; H10B 12/34; H10W 20/435; H10W 20/4451; H10W 46/00; H10W 46/503

(57) ABSTRACT

Disclosed are a semiconductor device capable of preventing a defect caused by a plasma-induced damage, and a method for fabricating the semiconductor device. The semiconductor device includes: a dummy gate structure including a dummy gate dielectric layer and a dummy gate electrode, which are disposed over a scribe lane region of a substrate; a first contact penetrating the dummy gate dielectric layer to contact the dummy gate electrode and the substrate; an inter-layer dielectric layer disposed over the dummy gate structure; a metal interconnection disposed over the inter-layer dielectric layer; and a second contact penetrating the inter-layer dielectric layer to electrically connect the gate electrode and the metal interconnection.

### CROSS-REFERENCE TO RELATED APPLICATION(S)

The present application claims priority under 35 U.S.C. 119(a) to Korean Patent Application No. 10-2025-0037267, filed on Mar. 24, 2025, which is incorporated herein by reference in its entirety.

### BACKGROUND

### 1. Field

Exemplary embodiments of the present disclosure relate to a semiconductor device, and more particularly, to a semiconductor device including a metal contact in a scribe lane, and a method for fabricating the semiconductor device.

### 2. Description of the Related Art

A process using plasma (which may be, hereinafter, referred to as a plasma process) is known to be applied in many processes for semiconductor fabrication. The plasma process is mainly used to deposit or etch diverse material layers. The characteristics of a device may deteriorate due to the electrons induced by the used plasma.

### SUMMARY

Embodiments of the present disclosure are directed to a semiconductor device capable of preventing a defect that may be caused by a plasma-induced damage, and a method for fabricating the semiconductor device.

In accordance with an embodiment of the present disclosure, a semiconductor device includes: a dummy gate structure including a dummy gate dielectric layer and a dummy gate electrode, which are disposed over a scribe lane region of a substrate; a first contact penetrating the dummy gate dielectric layer to connect the dummy gate electrode and the substrate; an inter-layer dielectric layer disposed over the dummy gate structure; a metal interconnection disposed over the inter-layer dielectric layer; and a second contact penetrating the inter-layer dielectric layer to electrically connect the gate electrode and the metal interconnection.

In accordance with another embodiment of the present disclosure, a semiconductor device includes: a substrate including a memory cell region and a scribe lane region; a bit line structure including a bit line contact disposed over the substrate of the memory cell region; a dummy gate structure including a dummy gate dielectric layer and a dummy gate electrode, which are disposed over the substrate of the scribe lane region; a first contact penetrating the dummy gate dielectric layer to connect the dummy gate electrode and the substrate; a peripheral inter-layer dielectric layer disposed over the dummy gate structure; a peripheral metal interconnection disposed over the peripheral inter-layer dielectric layer; and a second contact penetrating the peripheral inter-layer dielectric layer to electrically connect the dummy gate electrode and the peripheral metal interconnection.

In accordance with yet another embodiment of the present disclosure, a method for fabricating a semiconductor device includes: forming a first dielectric material layer over a scribe lane region of a substrate; forming a second dielectric material layer over a memory cell region of the substrate and over the first dielectric material layer of the scribe lane region; etching the second dielectric material layer of the memory cell region and the first and second dielectric material layers of the scribe lane region to form contact holes; and gap-filling the contact holes with a conductive material to form a bit line contact in the memory cell region and a dummy contact in the scribe lane region.

### BRIEF DESCRIPTION OF THE DRAWINGS

FIG. 1 is a plan view illustrating a semiconductor device in accordance with an embodiment of the present disclosure.

FIG. 2 is a cross-sectional view illustrating the semiconductor device in accordance with the embodiment of the present disclosure.

FIGS. 3A to 3H are cross-sectional views illustrating a method for fabricating a semiconductor device in accordance with an embodiment of the present disclosure.

### DETAILED DESCRIPTION

Exemplary embodiments of the present disclosure will be described below in more detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout the disclosure, like reference numerals refer to like parts throughout the various figures and embodiments of the present disclosure.

Hereinafter, the various embodiments of the present disclosure will be described in detail with reference to the attached drawings.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

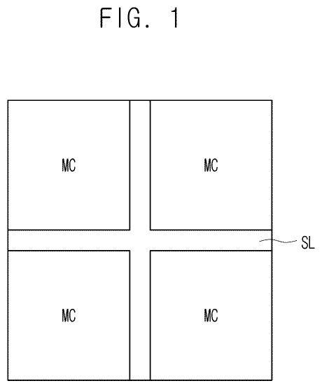

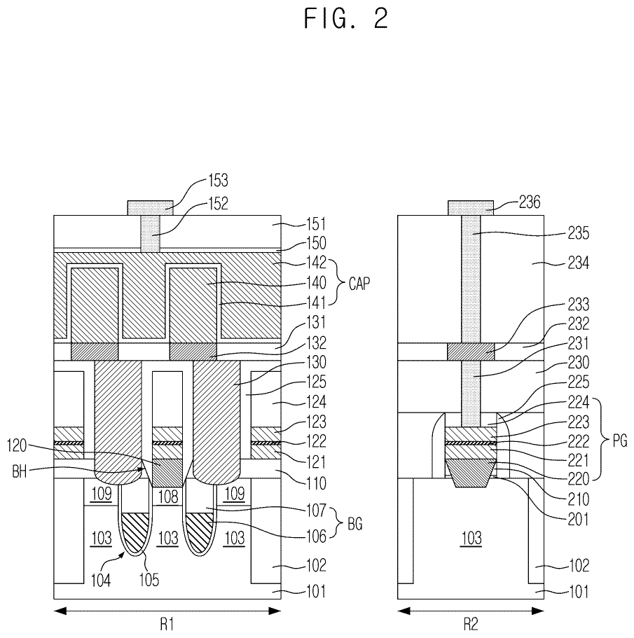

FIG. 1 is a plan view illustrating a semiconductor device in accordance with an embodiment of the present disclosure. FIG. 2 is a cross-sectional view illustrating the semiconductor device in accordance with the embodiment of the present disclosure.

Referring to FIG. 1, a substrate may include a main chip region MC and a scribe lane region SL. The main chip region MC may include a memory cell region and a peripheral circuit region. The scribe lane region SL may be disposed between the neighboring main chip regions MC to separate chips from each other. The scribe lane region SL may include a test pattern and an overlay key, or a dummy pattern that is used for the purpose of preventing roading during an etching process and a chemical mechanical polishing (CMP) process when an element in the main chip region MC is formed.

Referring to FIG. 2, the substrate 101 may include a first region R1 and a second region R2. The first region R1 may be a memory cell region. The memory cell region may be formed in the main chip region MC of FIG. 1. The second region R2 may be a scribe lane region SL (see FIG. 1).

The first region R1 of the substrate 101 may include a memory cell region in which elements such as a buried gate structure BG, a bit line structure BL, and a memory element CAP are formed. The second region R2 of the substrate 101 may be a region where a dummy pattern used for the purpose of preventing roading (for example, uneven or irregular etching) during the etching process and the chemical mechanical polishing (CMP) process is formed in the scribe lane region SL.

The substrate 101 may be a material suitable for semiconductor processing. The substrate 101 may include a semiconductor substrate. The substrate 101 may be formed of a material containing silicon. The substrate 101 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 101 may also include another semiconductor material, such as germanium. The substrate 101 may also include a III/V-group semiconductor substrate, for example, a compound semiconductor substrate, such as gallium arsenide (GaAs). The substrate 101 may also include a silicon-on-insulator (SOI) substrate.

The first region R1 and the second region R2 may be separated by an isolation layer 102, and each region may include an active region 103 that is defined by the isolation layer 102. The isolation layer 102 may be a shallow trench isolation region (STI) that is formed by a trench etching process. The isolation layer 102 may include silicon oxide, silicon nitride, or a combination thereof.

A buried gate structure BG may be disposed in the substrate 101 of the first region R1. The buried gate structure BG may include a buried gate structure disposed at a lower level than the top surface of the substrate 101. The embodiment of the present disclosure illustrates a buried gate structure which is disposed at a lower level than the top surface of the substrate 101, but the concept and spirit of the embodiment of the present disclosure are not limited thereto, and the embodiment of the present disclosure may be applied to all gate structures including a recess gate, a fin gate, a planar gate and the like.

The buried gate structure BG may include a gate dielectric layer 105 formed on the surface of a gate trench 104, a gate electrode 106 formed over the gate dielectric layer 105 to fill the gate trench 104, and a gate capping layer 107.

To be specific, a gate trench 104 of a line shape crossing the active region 103 and the isolation layer 102 in one direction may be formed in the substrate 101. The bottom surface of the gate trench 104 may be disposed at a higher level than the bottom surface of the isolation layer 102. In other words, the gate trench 104 may have a shallower depth than that of the isolation layer 102. The bottom portion of the gate trench 104 may have a curvature. According to another embodiment of the present disclosure, the isolation layer 102 in the direction that the gate trench 104 extends may be etched to a predetermined depth to form a fin in the active region 103.

A gate dielectric layer 105 may be formed on the surface of the gate trench 104. A gate electrode 106 filling a portion of the gate trench 104 may be formed over the gate dielectric layer 105. A gate capping layer 107, which may also be called a sealing layer, filling the remaining portion of the gate trench 104 may be formed over the gate electrode 106. The top surface of the gate capping layer 107 may be disposed at the same level as the top surface of the substrate 101. The top surface of the gate electrode 106 may be disposed at a lower level than the top surface of the substrate 101. The gate electrode 106 may include a low-resistance metal material. The gate electrode 106 may include a combination of at least one among a metal material, a metal nitride, and polysilicon, or stacked structure thereof. For example, the gate electrode 106 may be formed by sequentially stacking titanium nitride and tungsten. According to another embodiment of the present disclosure, the gate electrode 106 may be formed of titanium nitride only (TiN Only). According to another embodiment of the present disclosure, the gate electrode 106 may include a stacked structure of a metal material and polysilicon.

First and second impurity regions 108 and 109 may be formed in the substrate 101. The first and second impurity regions 108 and 109 may be referred to as ‘source/drain regions’. The first and second impurity regions 108 and 109 may be spaced apart from each other by the gate trench 104. Thus, the gate electrode 106 and the first and second impurity regions 108 and 109 may become a cell transistor. The cell transistor may improve the short channel effect due to the gate electrode 106 having a buried gate structure.

A first cell inter-layer dielectric layer 110 may be formed over the substrate 101.

A bit line contact 120 may be formed to penetrate the first cell inter-layer dielectric layer 110 over the substrate 101 to be coupled to the substrate 101. The bit line contact 120 may be coupled to the first impurity region 108. The bit line contact 120 may be disposed in a bit line contact hole BH. The bit line contact hole BH may expose the first impurity region 108. The bottom surface of the bit line contact 120 may be lower than the top surface of the substrate 101. The bit line contact 120 may be formed of polysilicon or a metal material. A portion of the bit line contact 120 may have a line width which is smaller than the diameter of the bit line contact hole BH. Accordingly, a gap may be formed on each side of the bit line contact 120. The gap may be formed independently on both sides of the bit line contact 120. As a result, one bit line contact 120 and a pair of gaps may be disposed in the bit line contact hole BH, and the pair of gaps may be separated by the bit line contact 120.

A bit line structure BL may be formed over the bit line contact 120. The bit line structure BL may be coupled to the active region by the bit line contact 120. The bit line structure BL may include a bit line 121, 122 and 123 and a bit line hard mask 124 over the bit line 121, 122 and 123. A portion of the bit line 121, 122 and 123 may be coupled to the bit line contact 120.

The line widths of the bit line 121, 122 and 123 and the bit line contact 120 may be the same. The bit line 121, 122 and 123 may include a metal material. The bit line 121, 122 and 123 may include a stacked structure of different metal materials. The bit line hard mask 124 may include a dielectric material.

A bit line spacer 125 may be formed on the sidewalls of the bit line contact 120 and the bit line structure BL. The bit line spacer 125 may extend from the sidewall of the bit line structure BL to the bit line contact 120. The bit line spacer 125 may fill a gap between the bit line contact 120 and the bit line contact hole BH.

The bit line spacer 125 may include a single-layer structure or a multi-layer structure. The bit line spacer 125 may include a dielectric material. The bit line spacer 125 may include at least one among silicon oxide, silicon nitride and a low-k material, or a combination of one or more of them.

A storage node contact 130 may be formed between the neighboring bit line structures BL. The storage node contact 130 may be coupled to the second impurity region 109.

A cell inter-layer dielectric layer 131 may be formed over the storage node contact 130. The cell inter-layer dielectric layer 131 may include a landing pad 132 that overlaps with at least a portion of the storage node contact 130. The landing pad 132 may penetrate the cell inter-layer dielectric layer 131.

A memory element CAP may be formed over the landing pad 132. According to the embodiment of the present disclosure, the memory element CAP may include a capacitor. The capacitor may include a stacked structure of a lower electrode 140, a dielectric layer 141, and an upper electrode 142. The capacitor may be coupled to the substrate 101 of the first region R1 by the landing pad 132 and the storage node contact 130.

The lower electrode 140 may have a pillar shape. According to another embodiment of the present disclosure, the lower electrode 140 may include a cylinder shape or a pylinder shape. According to yet another embodiment of the present disclosure, the lower electrode 140 may include a stacked structure of different materials. The lower electrode 140 may be a metal-based material. The metal-based material may refer to a metal-containing material.

The dielectric layer 141 may include a single-layer structure, a multi-layer structure, or a laminated structure. The dielectric layer 141 may be a doped structure or an intermixed structure. The dielectric layer 141 may include a high-k material. The dielectric layer 141 may have a higher dielectric constant than that of silicon oxide (SiO₂). The silicon oxide may have a dielectric constant of approximately 3.9, and the dielectric layer 141 may include a material having a dielectric constant of approximately 4 or greater. The high-k material may have a dielectric constant of approximately 20 or greater. The high-k material may include hafnium oxide (HfO₂), zirconium oxide (ZrO₂), aluminum oxide (Al₂O₃), titanium oxide (TiO₂), tantalum oxide (Ta₂O₅), niobium oxide (Nb₂O₅), or strontium titanium oxide (SrTiO₃). According to another embodiment of the present disclosure, the dielectric layer 141 may be formed of a composite layer including two or more layers of the aforementioned high-k materials. The dielectric layer 141 may be formed of a zirconium-based oxide. The dielectric layer 141 may have a stack structure including zirconium oxide (ZrO₂). The stack structure including zirconium oxide (ZrO₂) may include ZA (ZrO₂/Al₂O₃) or ZAZ (ZrO₂/Al₂O₃/ZrO₂). ZA may be a structure in which aluminum oxide is stacked over zirconium oxide. ZAZ may be a structure in which zirconium oxide, aluminum oxide, and zirconium oxide are sequentially stacked. ZrO₂, ZA, and ZAZ may be referred to as a zirconium oxide (ZrO₂)-based layer. According to another embodiment of the present disclosure, the dielectric layer 141 may be formed of hafnium (Hf)-based oxide. The dielectric layer 141 may be a stack structure including hafnium oxide (HfO₂). The stack structure including hafnium oxide (HfO₂) may include HA (HfO₂/Al₂O₃) or HAH (HfO₂/Al₂O₃/HfO₂). HA may be a structure in which aluminum oxide is stacked over hafnium oxide. HAH may be a structure in which hafnium oxide, aluminum oxide, and hafnium oxide are sequentially stacked. HfO₂, HA, and HAH may be referred to as a hafnium oxide (HfO₂)-based layer.

In the ZA, ZAZ, HA, and HAH, aluminum oxide (Al₂O₃) may have a larger bandgap than zirconium oxide (ZrO₂) and hafnium oxide (HfO₂). Aluminum oxide (Al₂O₃) may have a dielectric constant which is lower than the dielectric constants of zirconium oxide (ZrO₂) and hafnium oxide (HfO₂). Therefore, the dielectric layer 141 may include a stack of a high-k material and a high-bandgap material having a larger bandgap than that of the high-k material. In addition to aluminum oxide, the dielectric layer 141 may also include silicon oxide (SiO₂) as another high-bandgap material. The dielectric layer 141 may suppress leakage current by including a high bandgap material. The high bandgap material may be extremely thin. The high bandgap material may be thinner than the high-k material.

According to another embodiment of the present disclosure, the dielectric layer 141 may include a laminated structure in which high-k materials and a high bandgap materials are alternately stacked. For example, it may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, or a HAHAH (HfO₂/Al₂O₃/HfO₂/Al₂O₃/HfO₂) stack. In the laminated structure as above, the aluminum oxide (Al₂O₃) may be extremely thin. According to another embodiment of the present disclosure, the dielectric layer 141 may include a structure in which a first high-k material is doped with a second high-k material. For example, the dielectric layer 141 may include titanium oxide-doped zirconium oxide (TiO₂-doped ZrO₂) in which zirconium oxide (ZrO₂) is doped with titanium oxide (TiO₂). According to another embodiment of the present disclosure, the dielectric layer 141 may include a structure in which different high-k materials are intermixed. For example, it may include TiZrAlO in which zirconium oxide (ZrO₂), titanium oxide (TiO₂), and aluminum oxide (Al₂O₃) are intermixed.

The upper electrode 142 may include a silicon-containing material, a germanium-containing material, a metal-containing material, or a combination thereof. The upper electrode 142 may include a metal, a metal nitride, a metal carbide, a conductive metal oxide, or a combination thereof. The upper electrode 142 may include titanium (Ti), titanium nitride (TiN), tantalum nitride (TaN), titanium carbon nitride (TiCN), tantalum carbon nitride (TaCN), tungsten (W), tungsten nitride (WN), ruthenium (Ru), iridium (Ir), ruthenium oxide (RuO₂), iridium oxide (IrO₂), or a combination thereof. The upper electrode 142 may include a silicon layer (Si layer), a germanium layer (Ge layer), a silicon germanium layer (SiGe layer), or a combination thereof. The upper electrode 142 may be formed by stacking a silicon germanium layer over a silicon layer (Si/SiGe). The upper electrode 142 may be formed by stacking a silicon germanium layer over a germanium layer (Ge/SiGe). The upper electrode 142 may include a stack of a silicon-containing material and a metal-containing material. The upper electrode 142 may be formed by stacking a silicon germanium layer and a metal nitride. The upper electrode 142 may be formed by stacking silicon germanium and tungsten nitride over titanium nitride (TiN/SiGe/WN).

A cell metal interconnection 153 may be disposed over the memory element CAP of the first region R1. The cell metal interconnection 153 may be disposed at a higher level than the top surface of the memory element CAP. An etch stop layer 150 and a third cell inter-layer dielectric layer 151 may be disposed between the cell metal interconnection 153 and the memory element CAP.

The cell metal interconnection 153 may be coupled to the memory element CAP through a cell metal interconnection contact 152. The cell metal interconnection contact 152 may penetrate the third cell inter-layer dielectric layer 151 and have one end contact the upper electrode 142 of the memory element CAP and the other end contact the cell metal interconnection 153.

The substrate 101 of the second region R2 may include a dummy gate PG and a peripheral metal interconnection 236.

The dummy gate PG may be used for the purpose of preventing roading in an etching process and a planarization process when the element of the first region R1 is formed. The dummy gate PG may include a stacked structure of a dummy gate dielectric layer 202, a dummy gate electrode 221, 222 and 223, and a dummy gate hard mask 224. A first peripheral inter-layer dielectric layer 210 may be disposed between the dummy gate dielectric layer 202 and the dummy gate electrode 221, 222 and 223. According to another embodiment of the present disclosure, the first peripheral inter-layer dielectric layer 210 may be removed. A dummy gate spacer 225 may be formed on the sidewall of the dummy gate PG.

In particular, according to the embodiment of the present disclosure, a dummy contact 220 may be formed below the dummy gate electrode 221, 222 and 223 to electrically connect the dummy gate electrode 221, 222 and 223 and the substrate 101.

The dummy contact 220 may penetrate the first peripheral inter-layer dielectric layer 210 and the dummy gate dielectric layer 202 and may have both ends of the dummy contact 220 contact the dummy gate electrode 221, 222 and 223 and the substrate 101 by being disposed between the dummy gate electrode 221, 222 and 223 and the substrate 101.

The dummy contact 220 may have a sloped profile that narrows in width as it approaches the substrate 101. That is, a width of the dummy contact 220 may narrow from a top surface of the dummy contact 220 to a bottom surface of the dummy contact 220. A width of the top surface of the dummy contact 220 may be wider than a width of the bottom surface of the dummy contact 220.

The dummy contact 220 may be formed simultaneously during the bit line contact 120 process. The dummy contact 220 may include the same material as that of the bit line contact 120. For example, the dummy contact 220 may include polysilicon.

A dummy gate spacer 225 may be formed on both sidewalls of the dummy gate PG.

A second peripheral inter-layer dielectric layer 226 may be formed over the substrate 101 between the dummy gates PG.

Third to fifth peripheral inter-layer dielectric layers 230, 232 and 234 may be formed over the second peripheral inter-layer dielectric layer 226 and the dummy gates PG.

A first peripheral metal interconnection 233 may be formed over the third peripheral inter-layer dielectric layer 230, and a second peripheral metal interconnection 236 may be formed over the fifth peripheral inter-layer dielectric layer 234.

The second peripheral metal interconnection 236 and the first peripheral metal interconnection 233 may be electrically connected by the second peripheral metal contact 235 penetrating the fifth peripheral inter-layer dielectric layer 234. The first peripheral metal interconnection 233 and the dummy gate PG may be electrically connected to the dummy gate electrode 221, 222 and 223 by the first peripheral metal contact 231 penetrating the third peripheral inter-layer dielectric layer 230 and the dummy gate hard mask 224.

As described above, according to the embodiment of the present disclosure, a current path may be formed from the second peripheral metal interconnection 236 to the substrate 101 by forming the dummy contact 220 between the dummy gate electrode 221, 222 and 223 and the substrate 101.

Therefore, it is possible to prevent a defect that may be caused due to a plasma-induced damage by naturally discharging the plasma ions coming from the top portion to the substrate 101 through the current path.

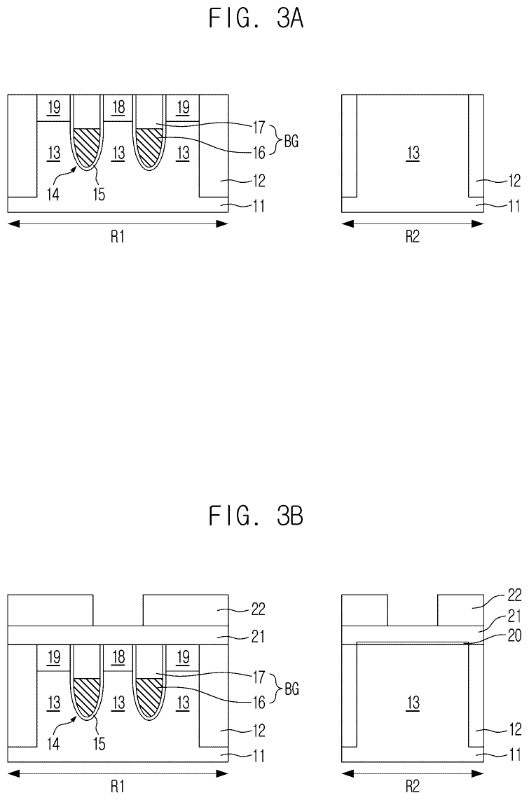

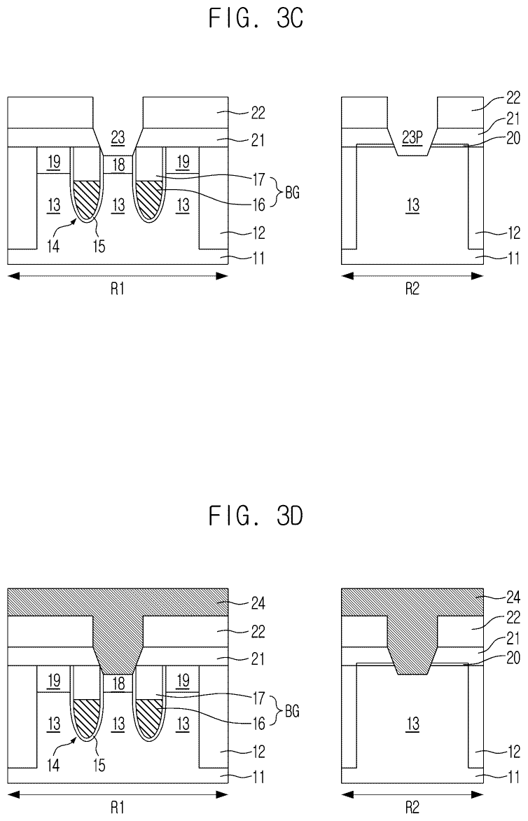

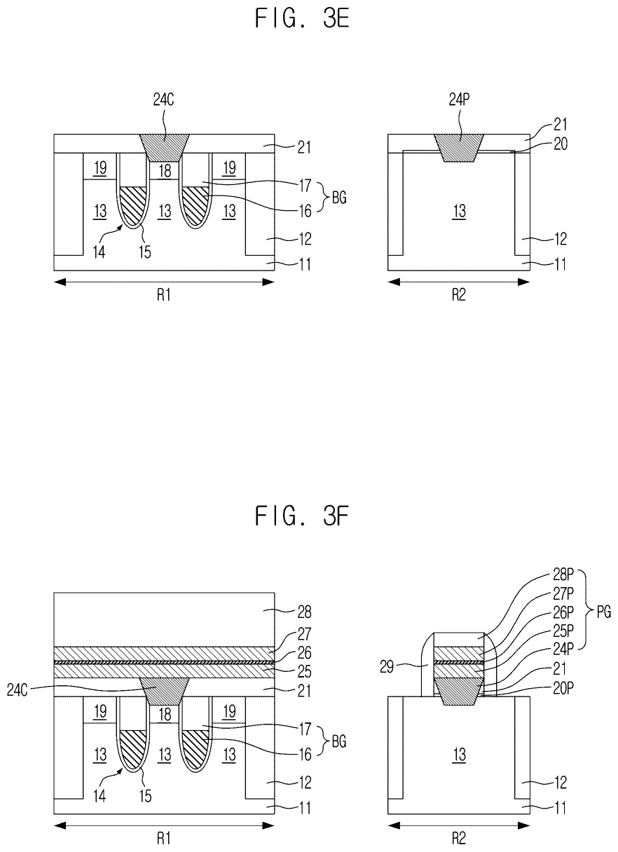

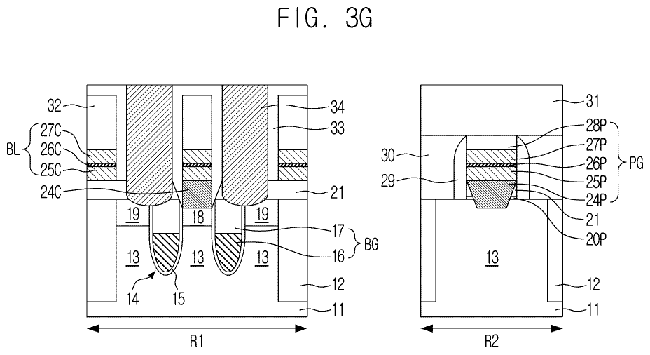

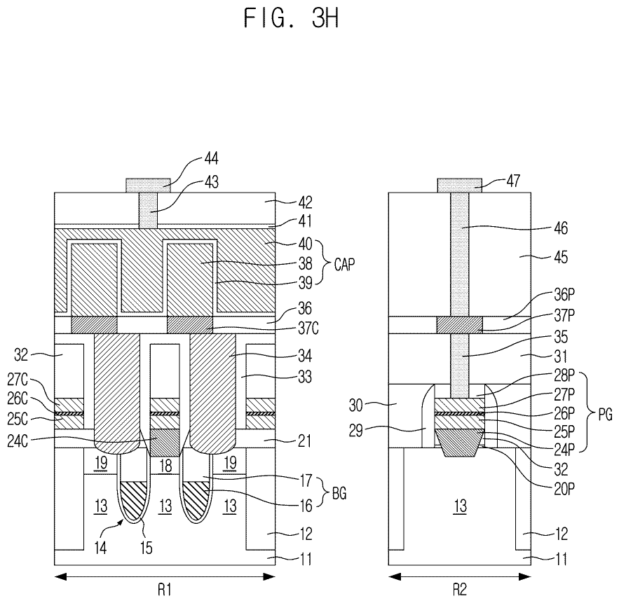

FIGS. 3A to 3H are cross-sectional views illustrating a method for fabricating a semiconductor device in accordance with an embodiment of the present disclosure.

Referring to FIG. 3A, the substrate 11 may include a first region R1 and a second region R2. The first region R1 may be a memory cell region. The second region R2 may be a scribe lane region.

The substrate 11 may be a material suitable for semiconductor processing. The substrate 11 may include a semiconductor substrate. The substrate 11 may be formed of a material containing silicon. The substrate 11 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 11 may also include another semiconductor material, such as germanium. The substrate 11 may also include a III/V-group semiconductor substrate, for example, a compound semiconductor substrate, such as gallium arsenide (GaAs). The substrate 11 may also include a silicon-on-insulator (SOI) substrate.

The first region R1 and the second region R2 may be isolated by the isolation layer 12, and each region may include an active region 13 that is defined by the isolation layer 12. The isolation layer 12 may be a shallow trench isolation region (STI) that is formed by a trench etching process. The isolation layer 12 may include silicon oxide, silicon nitride, or a combination thereof. A Chemical Vapor Deposition (CVD) process or another deposition process may be performed to fill the isolation trench with a dielectric material. A planarization process such as a chemical mechanical polishing (CMP) may additionally be used.

Subsequently, a buried gate structure BG may be formed in the substrate 11 of the first region R1. The buried gate structure BG may include a gate trench 15, a gate dielectric layer 16 covering the bottom surface and sidewalls of the gate trench 15, a gate electrode 17 filling a portion of the gate trench 15 over the gate dielectric layer 16, and a gate capping layer 18 formed over the gate electrode 17.

A method of forming the buried gate structure BG may be as follows.

First, a gate trench 14 may be formed in the substrate 11. The gate trench 14 may have a line shape crossing the active region 13 and the isolation layer 12. The gate trench 14 may be formed by forming a mask pattern (not shown) over the substrate 11 and performing an etching process with the mask pattern used as an etching mask. The gate trench 14 may be formed to be shallower than the isolation trench. In other words, the bottom surface of the gate trench 14 may be disposed at a higher level than the bottom surface of the isolation layer 12. The depth of the gate trench 14 may have a sufficient depth to increase the average cross-sectional area of the gate electrode 16. Accordingly, the resistance of the gate electrode 16 may be reduced. According to another embodiment of the present disclosure, the bottom edges of the gate trench 14 may have a curvature. By forming the bottom edges of the gate trench 14 to have a curvature, the unevenness in the bottom portion of the gate trench 14 may be minimized, and thus, the filling of the gate electrode 16 may be easily performed.

Subsequently, a gate dielectric layer 15 may be formed on the bottom surface and sidewalls of the gate trench 14. Before the gate dielectric layer 15 is formed, the etching damage on the surface of the gate trench 14 may be cured. For example, after a sacrificial oxide is formed by a thermal oxidation process, the sacrificial oxide may be removed.

The gate dielectric layer 15 may be formed by a thermal oxidation process. For example, the gate dielectric layer 15 may be formed by oxidizing the bottom surface and sidewalls of the gate trench 14.

According to another embodiment of the present disclosure, the gate dielectric layer 15 may be formed by a deposition method such as chemical vapor deposition (CVD) or atomic layer deposition (ALD). The gate dielectric layer 15 may include a high-k material, an oxide, a nitride, an oxynitride, or a combination thereof. The high-k material may include a hafnium-containing material. The hafnium-containing material may include hafnium oxide, hafnium silicon oxide, hafnium silicon oxynitride, or a combination thereof. According to another embodiment of the present disclosure, the high-k material may include lanthanum oxide, lanthanum aluminum oxide, zirconium oxide, zirconium silicon oxide, zirconium silicon oxynitride, aluminum oxide, or a combination thereof. Other known high-k materials may be selectively used as the high-k material.

According to another embodiment of the present disclosure, the gate dielectric layer 15 may be formed by depositing a liner polysilicon layer and then radical-oxidizing the liner polysilicon layer.

According to yet another embodiment of the present disclosure, the gate dielectric layer 15 may be formed by forming a liner silicon nitride layer and then radical-oxidizing the liner silicon nitride layer.

Subsequently, a gate electrode 16 may be formed over the gate dielectric layer 15. To form the gate electrode 16, a conductive layer (not shown) may be formed to fill the gate trench 14, and then a recessing process may be performed. The recessing process may be performed by performing an etch-back process, or by sequentially performing a Chemical Mechanical Polishing (CMP) process and an etch-back process. The gate electrode 16 may have a recessed shape that fills a portion of the gate trench 14. In other words, the top surface of the gate electrode 16 may be disposed at a lower level than the top surface of the substrate 11. The gate electrode 16 may include a metal, a metal nitride, or a combination thereof. For example, the gate electrode 16 may be formed of titanium nitride (TiN), tungsten (W), or a stack of titanium nitride/tungsten (TiN/W). The titanium nitride/tungsten (TiN/W) stack may have a structure in which titanium nitride is conformally formed and then a portion of the gate trench 14 is filled with tungsten. Titanium nitride may be used alone as the gate electrode 16, and this may be referred to as a gate electrode 16 having a ‘TiN-only’ structure. According to another embodiment of the present disclosure, the gate electrode 16 may include a stacked structure of a metal and polysilicon.

Subsequently, a gate capping layer 17 may be formed over the gate electrode 16. The gate capping layer 17 may include a dielectric material. The remaining portion of the gate trench 14 over the gate electrode 16 may be filled with the gate capping layer 17. The gate capping layer 17 may include silicon oxide. According to yet another embodiment of the present disclosure, the gate capping layer 17 may have a Nitride-Oxide-Nitride (NON) structure. The top surface of the gate capping layer 17 may be disposed at the same level as the top surface of the substrate 11.

After the buried gate structure is formed as described above, a first source/drain region 18 and a second source/drain region 19 may be formed. The first source/drain region 18 and the second source/drain region 19 may be formed by a doping process such as implantation. The first source/drain region 18 and the second source/drain region 19 may have the same depth. According to another embodiment of the present disclosure, the first source/drain region 18 may be deeper than the second source/drain region 19. The first source/drain region 18 may be a region to which a bit line contact is coupled. The second source/drain region 19 may be a region to which a storage contact is coupled.

A cell transistor of a memory cell may be formed by the gate electrode 16, the first source/drain region 18, and the second source/drain region 19.

Referring to FIG. 3B, a first dielectric material layer 20 may be formed over the substrate 11 of the second region R2. The first dielectric material layer 20 may be a dielectric material for forming a peripheral gate dielectric layer. The first dielectric material layer 20 may be formed through a thermal oxidation process, but the concept and spirit of the embodiment of the present disclosure are not limited thereto.

A second dielectric material layer 21 may be formed over the substrate 11 of the first region R1 and the substrate 11 of the second region R2 including the first dielectric material layer 20. The second dielectric material layer 21 may be a mold layer for providing an inter-layer dielectric layer and a contact region. The second dielectric material layer 21 may have a single-layer structure or a multi-layer structure.

A mask pattern 22 may be formed over the second dielectric material layer 21. The mask pattern 22 may define a bit line contact region. According to the embodiment of the present disclosure, the mask pattern 22 may be formed in each of the first region R1 and the second region R2.

Referring to FIG. 3C, contact holes 23 and 23P that expose the substrate 11 may be formed by etching the second dielectric material layer 21 of the first region R1 and the second dielectric material layer 21 and the first dielectric material layer 20 of the second region R2.

The contact holes 23 and 23P may have a circular shape or an oval shape. A portion of the substrate 11 of the first region R1 and the second region R2 may be exposed by the contact holes 23 and 23P. The contact holes 23 and 23P may be formed to expose a portion of the active region 13 of each region.

The contact hole 23 of the first region R1 may be referred to as a ‘bit line contact hole 23’. The contact hole 23P of the second region R2 may be referred to as a ‘dummy contact hole 23P’.

The bit line contact hole 23 may expose the first doped region 18. In the etching process for forming the bit line contact hole 23, a portion of the first doped region 18, the isolation layer 12, and the gate capping layer 17 may be etched. In other words, the gate capping layer 17, the first doped region 18, and the isolation layer 12 below the bit line contact hole 23 may be recessed to a predetermined depth. Accordingly, the bottom portion of the bit line contact hole 23 may extend into the substrate 11. As the bit line contact hole 23 extends, the first doped region 18 may be recessed, and the top surface of the first doped region 18 may be disposed at a lower level than the top surface of the second doped region 19.

The dummy contact hole 23P may expose the active region of the second region R2. In the etching process for forming the dummy contact hole 23P, the substrate 11 of the second region R2 may be partially etched. In other words, the bottom surface of the dummy contact hole 23P may be disposed at a lower level than the top surface of the substrate 11.

The bit line contact hole 23 and the dummy contact hole 23P may be formed simultaneously through the same etching process. The bit line contact hole 23 and the dummy contact hole 23P may be formed in the same shape through the same mask process. The bottom surface of the bit line contact hole 23 and the bottom surface of the dummy contact hole 23P may be disposed at the same level, but the concept and spirit of the embodiment of the present disclosure are not limited thereto, and the height of the bottom surface may be different based on the etching selectivity of each layer.

Referring to FIG. 3D, a conductive material 24 that gap-fills the bit line contact hole 23 and the dummy contact hole 23P may be formed. The conductive material 24 may gap-fill the bit line contact hole 23 and the dummy contact hole 23P and may be formed over the mask pattern 22. For example, the conductive material 24 may include polysilicon.

Referring to FIG. 3E, a bit line contact 24C and a dummy contact 24P may be formed in the first region R1 and the second region R2, respectively. To form the bit line contact 24C and the dummy contact 24P, the conductive material 24 (see FIG. 3D) may be etched targeting to expose the top surface of the second dielectric material layer 21. For example, the etching of the conductive material 24 may include a chemical mechanical polishing (CMP) process or an etch-back process.

The dummy contact 24P may have a sloped profile that narrows in width as it approaches the substrate 11. That is, a width of the dummy contact 24P may narrow from a top surface of the dummy contact 24P to a bottom surface of the dummy contact 24P. A width of the top surface of the dummy contact 24P may be wider than a width of the bottom surface of the dummy contact 24P.

Referring to FIG. 3F, a dummy gate structure PG may be formed in the second region R2. The dummy gate structure PG may include a stacked structure of a dummy gate electrode 24P, 25P and 26P and a dummy gate hard mask 28P. Dummy gate spacers 29 may be formed on both sidewalls of the dummy gate structure PG.

A method of forming the dummy gate structure PG may be as follows.

First, first to third conductive materials 25, 26 and 27 may be sequentially formed over the second inter-layer dielectric layer 21 including the bit line contact 24C and the dummy contact 24P. The first to third conductive materials 25, 26 and 27 may have a stacked structure for forming a bit line of the first region R1 and a dummy gate electrode of the second region R2.

Subsequently, a hard mask layer 28 may be formed over the third conductive material 27.

Subsequently, a mask pattern may be formed over the hard mask layer 28 of the second region R2. The mask pattern may define a dummy gate in the second region R2. The mask pattern may be formed on the profile of the hard mask layer 28 of the first region R1.

Subsequently, the hard mask layer 28, the first to third conductive materials 25, 26 and 27, the second dielectric material layer 21, and the first dielectric material layer 20 of the second region R2 may be sequentially etched by using the mask pattern.

Subsequently, a dummy gate spacer 29 may be formed on both sidewalls of the dummy gate structure PG.

In particular, according to the embodiment of the present disclosure, in the dummy gate structure PG, the dummy contact 24P may electrically connect the dummy gate electrode 24P, 25P, and 26P and the substrate 11. Therefore, when only the dummy gate dielectric layer 20P is disposed between the dummy gate electrode 24P, 25P, and 26P and the substrate 11, an arcing phenomenon that may occur due to a plasma-induced damage may be prevented.

Referring to FIG. 3G, a first peripheral inter-layer dielectric layer 30 may be formed over the substrate 11 of the second region R2 including the dummy gate structure PG.

Subsequently, the cell open mask 31 that opens the first region R1 may be formed over the first peripheral inter-layer dielectric layer 30.

Subsequently, a bit line structure BL may be formed over the substrate 11 of the first region R1.

The bit line contact 24C may electrically connect the bit line structure BL to the substrate 11. The bit line structure BL may include a bit line 25C, 26C, and 27C and a bit line hard mask 32 over the bit line 25C, 26C, and 27C. A portion of the bit line 25C, 26C, and 27C may be coupled to the bit line contact 24C.

Subsequently, a bit line spacer 33 may be formed on the sidewalls of the bit line contact 24C and the bit line structure BL. The bit line spacer 33 may extend from the sidewall of the bit line structure BL to the bit line contact 24C.

The bit line spacer 33 may include a single-layer structure or a multi-layer structure. The bit line spacer 33 may include a dielectric material. The bit line spacer 33 may include at least one among silicon oxide, silicon nitride, and a low-k material, or a combination thereof.

Subsequently, a storage node contact 34 may be formed between the neighboring bit line structures BL. The storage node contact 34 may be coupled to the second impurity region 19.

Referring to FIG. 3H, a second peripheral inter-layer dielectric layer 31 may be formed over the first peripheral inter-layer dielectric layer 30 including the dummy gate structure PG.

Subsequently, a first peripheral metal interconnection contact 35 penetrating the second peripheral inter-layer dielectric layer 31 and the dummy gate hard mask 28P may be formed.

Subsequently, a first cell inter-layer dielectric layer 36 and a third peripheral inter-layer dielectric layer 36P may be formed over the bit line structure BL including the storage node contact 34 of the first region R1 and the second peripheral inter-layer dielectric layer 31 of the second region R2, respectively.

Subsequently, a landing pad 37C penetrating the first cell inter-layer dielectric layer 36 and overlapping with at least a portion of the storage node contact 34 may be formed. At the same time, a first peripheral metal interconnection 37P penetrating the third peripheral inter-layer dielectric layer 36P and contacting the first peripheral metal interconnection contact 35 may be formed.

Subsequently, a capacitor CAP contacting the landing pad 37C of the first region R1 may be formed. The capacitor CAP may include a stacked structure of a lower electrode 38, a dielectric layer 39, and an upper electrode 40.

Subsequently, an etch stop layer 41 and a second cell inter-layer dielectric layer 42 may be sequentially formed over the capacitor CAP of the first region R1. Here, a fourth peripheral inter-layer dielectric layer 45 may be formed over the third inter-layer dielectric layer 36P of the second region R2.

Subsequently, a cell metal interconnection contact 43 may be formed to be electrically connected to the capacitor CAP by penetrating the second cell inter-layer dielectric layer 42 and the etch stop layer 41. Here, a second peripheral metal interconnection contact 46 may be formed to be coupled to the first peripheral metal interconnection 37P by penetrating the third peripheral inter-layer dielectric layer 36P of the second region R2.

Subsequently, a cell metal interconnection 44 may be formed over the second cell inter-layer dielectric layer 42 to contact the cell metal interconnection contact 43. Here, a second peripheral metal interconnection 47 may be formed over the fourth peripheral inter-layer dielectric layer 45 of the second region R2 to be coupled to the second peripheral metal interconnection contact 46.

According to the embodiment of the present disclosure, it is possible to prevent a defect that may be caused by a plasma-induced damage by forming a path for discharging electrons induced by plasma to the substrate.

While the present disclosure has been described with respect to the specific embodiments, it will be apparent to those skilled in the art that various changes and modifications may be made without departing from the spirit and scope of the disclosure as defined in the following claims.

What is claimed is:

1. A semiconductor device comprising:
a dummy gate structure including a dummy gate dielectric layer and a dummy gate electrode, which are disposed over a scribe lane region of a substrate;
a first contact penetrating the dummy gate dielectric layer to connect the dummy gate electrode and the substrate;
an inter-layer dielectric layer disposed over the dummy gate structure;
a metal interconnection disposed over the inter-layer dielectric layer; and
a second contact penetrating the inter-layer dielectric layer to electrically connect the gate electrode and the metal interconnection.

2. The semiconductor device of claim 1, wherein a bottom surface of the first contact is disposed at a lower level than a top surface of the substrate.

3. The semiconductor device of claim 1, wherein the first contact has widths which narrows as the first contact approaches the substrate.

4. The semiconductor device of claim 1, wherein the first contact includes polysilicon.

5. The semiconductor device of claim 1, wherein the second contact includes a metal material.

6. A semiconductor device comprising:
a substrate including a memory cell region and a scribe lane region;
a bit line structure including a bit line contact disposed over the memory cell region;
a dummy gate structure including a dummy gate dielectric layer and a dummy gate electrode, which are disposed over the scribe lane region;
a first contact penetrating the dummy gate dielectric layer to connect the dummy gate electrode and the substrate;
a peripheral inter-layer dielectric layer disposed over the dummy gate structure;
a peripheral metal interconnection disposed over the peripheral inter-layer dielectric layer; and
a second contact penetrating the peripheral inter-layer dielectric layer to electrically connect the dummy gate electrode and the peripheral metal interconnection.

7. The semiconductor device of claim 6, wherein the bit line contact and the first contact are disposed at a same level.

8. The semiconductor device of claim 6, wherein a bottom surface of the first contact is disposed at a lower level than a top surface of the substrate.

9. The semiconductor device of claim 6, wherein the first contact includes polysilicon.

10. The semiconductor device of claim 6, wherein the second contact includes a metal material.
